(19) United States
(12) Patent Application Publication
(10) Pub. No.: US 2020/0074290 A1
(43) Pub. Date: Mar. 5, 2020

(54) COMPLEX VALUED GATING MECHANISMS

(71) Applicant: Element AI Inc., Montreal (CA)

(72) Inventors: Chiheb TRABELSI, Montreal (CA); Ying ZHANG, Montreal (CA); Ousmane Amadou DIA, Montreal (CA); Christopher Joseph PAL, Montreal (CA); Negar ROSTAMZADEH, Montreal (CA)

(21) Appl. No.: 16/556,316

(22) Filed: Aug. 30, 2019

Related U.S. Application Data
(60) Provisional application No. 62/724,791, filed on Aug. 30, 2018.

(51) Int. Cl. G06N 3/063; G11C 11/54; G11C 11/34

(52) U.S. Cl. CPC G06N 3/0635; G11C 11/34; G11C 11/54

(57) ABSTRACT

Systems and methods relating to neural networks. More specifically, the present invention relates to complex valued gating mechanisms which may be used as neurons in a neural network. A novel complex gated recurrent unit and a novel complex recurrent unit use real values for amplitude normalization to stabilize training while retaining phase information.

### RELATED APPLICATIONS

This application is a non provisional patent application which claims the benefit of U.S. Provisional Application No. 62/724,791 filed on Aug. 30, 2018.

### TECHNICAL FIELD

The present invention relates to neural networks. More specifically, the present invention relates to gating mechanisms which can be used as neurons in neural networks.

### BACKGROUND

Complex-valued neural networks have been studied since long before the emergence of modern deep learning techniques [10, 32, 20, 13, 23]. Nevertheless, deep complex-valued models have only just started to emerge [24, 1, 4, 28, 19], with the great majority of models in deep learning still relying on real-valued representations. The motivation for using complex-valued representations for deep learning is twofold: On the one hand, biological nervous systems actively make use of synchronization effects to gate signals between neurons—a mechanism that can be recreated in artificial systems by taking into account phase differences. On the other hand, complex-valued representations are better suited to express certain types of data, particularly such that are naturally represented in the frequency domain.

In biological nervous systems, functional sub-networks can dynamically form through synchronization, that is, by either aligning or misaligning the respective phases of groups of neurons. Effectively, such synchronization-based modulation of interactions can be considered a pairwise gating mechanism, where there are as many individually controllable gates as there are connections between units. This is in contrast to typical gated unit models, such as LSTM or GRU, where gates are global per unit, and a single unit is either accessible by all other units or by none at each time-step. A finer-grained, pairwise gating mechanism can potentially implement a more powerful model of computation than a system with global per-unit gates. Aspects of neural synchronization have been explored in biologically inspired deep networks, where phase differences of neurons lead to constructive or destructive interference [24]. Moreover, as shown in [28], the notion of neural synchrony is related to the gating mechanisms implemented in Long Short-Term Memory cells (LSTMs) [15] and Gated Recurrent Units (GRUs) [3]: synchronized inputs correspond to neurons whose control gates are simultaneously open. An explicit phase representation through complex-values could thus be advantageous in recurrent neural networks from a computational point of view.

Prior work [28] has provided building blocks for deep complex-valued neural networks. On the one hand, in these models, complex representations have been shown to avoid numerical problems during training. On the other hand, complex-valued representations are well suited for audio or other frequency domain signals, as complex representations have the capacity to explicitly encode and manipulate frequency magnitude and phase components of a signal. In particular, previous models have excelled at tasks such as automatic music transcription and spectrum prediction.

Besides the biological and representational benefits of using complex-valued representations, working with RNNs (recurrent neural networks) in the spectral (frequency) domain has computational benefits. In particular, short-time Fourier transforms STFTs can be used to considerably reduce the temporal dimension of the signal. This is a critical advantage, as training recurrent neural networks on long sequences remains challenging due to unstable gradients and computational requirements of backpropagation through time (BPTT) [14, 2]. Applying the STFT on the raw signal, on the other hand, is computationally efficient, as in practice it is implemented with the Fast Fourier Transform (FFT) whose computational complexity is O(n log(n)).

The illustrated biological, representational and computational reasons provide a clear motivation for designing recurrent complex-valued models for tasks where the complex-valued representation of the input and output data is more valuable than their real-counterpart.

### SUMMARY

The present invention provides systems and methods relating to neural networks. More specifically, the present invention relates to complex valued gating mechanisms which may be used as neurons in a neural network. A novel complex gated recurrent unit and a novel complex recurrent unit use real values for amplitude normalization to stabilize training while retaining phase information.

In a first aspect, the present invention provides a method for determining a state of a gating mechanism in a neural network, the method comprising:
a) determining an immediately preceding state vector representing an immediately previous state of said gating mechanism;
b) receiving an input vector;
c) performing an element-wise multiplication between an update gate vector and a candidate state vector;
d) performing an element-wise multiplication between a difference between 1 and said update gate vector and said immediately preceding state vector;
e) adding a result of step c and step d to result in a current state vector representing said state of said gating mechanism;
wherein said update gate vector is based on said input vector, said immediately preceding state vector, an update bias vector, and at least one weight matrix.

In a second aspect, the present invention provides a system for determining a current state of a gating mechanism in a neural network, the system comprising:
a candidate module for determining a candidate state for said gating mechanism based on:
an input vector,
an immediately preceding state vector representing an immediately previous state of said gating mechanism,
at least one candidate weight matrix, and
a candidate bias vector;
an update gate module for determining an update gate vector based on:
said input vector;
said immediately preceding state vector;
an update bias vector; and
at least one update weight matrix;
   wherein
a result of said candidate module and a result of said update gate module are multiplied in an element-wise manner to result in a first intermediate product;
a result of said update gate module and said immediately preceding state vector are multiplied in an element-wise manner to result in a second intermediate product;
a sum of said first intermediate product and said second intermediate product results in said current state of said gating mechanism.

### BRIEF DESCRIPTION OF THE DRAWINGS

The embodiments of the present invention will now be described by reference to the following figures, in which identical reference numerals in different figures indicate identical elements and in which:

FIG. 1 is a schematic diagram of a complex gated recurrent unit according to one aspect of the invention; and

FIG. 2 is a schematic diagram of a complex recurrent unit according to another aspect of the present invention.

### DETAILED DESCRIPTION

To better understand the present invention, the reader is directed to the listing of citations at the end of this description. For ease of reference, these citations and references have been referred to by their listing number throughout this document. The contents of the citations in the list at the end of this description are hereby incorporated by reference herein in their entirety.

In one aspect of the present invention, there is provided a Complex Gated Recurrent Unit (CGRU). A Complex Gated Recurrent Unit (CGRU) is similar to a real-valued Gated Recurrent Unit (GRU). The only difference is that, instead of using real-valued matrix multiplications to perform computation, complex-valued operations are used. The computation in a CGRU is defined as follows:

zₜ=σ(W_{xz}⊗xₜ+W_{hz}⊗hₜ₋₁+b_{z})

rₜ=σ(Wₓᵣ⊗xₜ+Wₕᵣ⊗hₜ₋₁+bᵣ)

\tilde{h}ₜ=tanh([W_{x\tilde{h}}⊗xₜ+rₜ∘(W_{h\tilde{h}}⊗hₜ₋₁)]+b_{\tilde{h}})

hₜ=zₜ∘\tilde{h}ₜ+(1−zₜ)∘hₜ₋₁, (1)

In the above formulations, σ denotes the element-wise sigmoidal activation function and ⊗ denotes the complex-valued matrix multiplication (a complex-valued matrix-vector product). Note that ∘ represents an element-wise multiplication while ⊚ denotes a real-valued matrix-vector product. As is the case in [4, 28], the gates act multiplicatively in an element-wise fashion. zₜ, rₜ, \tilde{h}ₜ represent the vector notation of what we call the update gate, the reset gate and the candidate state, respectively. b_{z}, bᵣ and bₕ- represent the vector notation of the corresponding biases. These biases are vectors and hₜ is the vector notation of the hidden state. All of the vectors belong to [symbol] ^{d}, where d is the complex hidden size. Similar to the complex LSTM model for each of the gates, W_{xgate}∈ [symbol] ^{d×i} and W_{hgate}∈ [symbol] ^{d×d} are the input-to-hidden and hidden-to-hidden weights, respectively, where i is the input dimension. For clarity, these weight matrices include W_{xz} and W_{hz} for the update gate, Wₓᵣ and Wₕᵣ for the reset gate, and Wₓₕ and Wₕₕ for the candidate state.

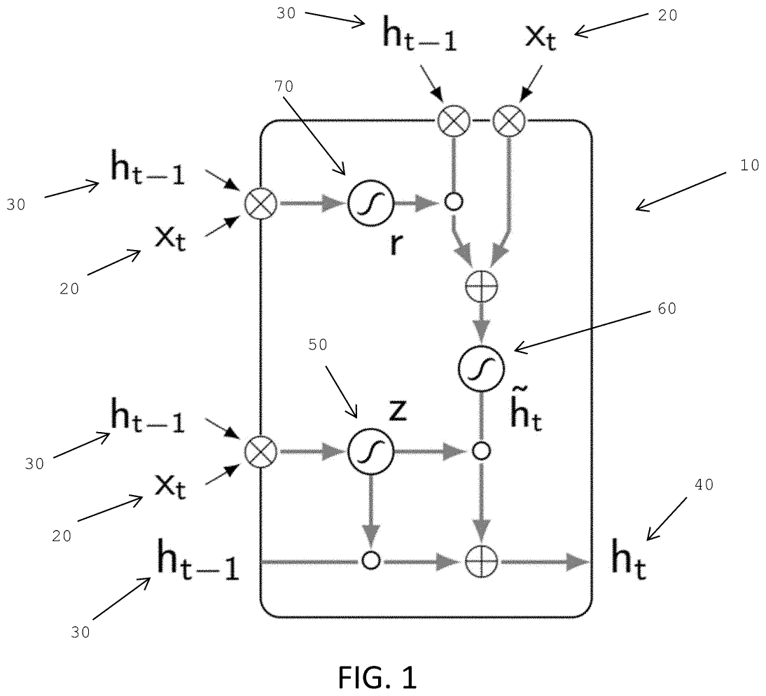

Referring to FIG. 1, a block diagram of the gate mechanism for a CGRU is illustrated. As can be seen, the gating mechanism 10 has, as input, an input vector xₜ 20 and an immediately preceding state vector hₜ₋₁ 30 that represents the immediately preceding or immediately previous state of the mechanism 10. The output hₜ 40 is the current state of the gate mechanism and is, from Equation (1), a function of the results of update gate zₜ 50 and of the candidate state \tilde{h}ₜ 60. This candidate state is a result of operations between the two inputs 20, 30 and the result of the reset gate rₜ 70. At the same time, the update gate is a result of operations between the two inputs 20, 30. Not shown in the Figure (and yet reflected in Equation (1)) are the weights for each of the gates as well as the bias vectors, with each gate having its own bias vector. Each gate, similarly, has its own weight matrices, as can be seen from Equation (1).

In another aspect, the present invention provides a Complex Recurrent Unit (CRU) that is similar to a complex-valued Gated Recurrent Unit (CGRU). The CRU formulation presented uses a real-valued modulation gate mₜ∈ [symbol] ^{d} that interacts with both the complex-valued input xₜ and the complex-valued hidden state at the previous time step hₜ₋₁ (i.e. the immediately preceding state of the gate mechanism). The interaction is realized by an element-wise multiplication ∘. The modulation gate acts identically on both the real and the imaginary parts of a complex-valued neuron. More precisely, the modulus of each complex-valued neuron in

[W_{x\tilde{h}}⊗xₜ+W_{h\tilde{h}}⊗hₜ₋₁]

is multiplied by its corresponding value in the modulation gate. The computation in a CRU is defined as follows:

zₜ=σ(W_{xz}⊗xₜ+W_{hz}⊗hₜ₋₁+b_{z})

mₜ=modact(Wₓₘxₜ+Wₕₘhₜ₋₁+bₘ)

\tilde{h}ₜ=tanh(mₜ∘[W_{x\tilde{h}}⊗xₜ+W_{h\tilde{h}}⊗hₜ₋₁]+b_{\tilde{h}})

hₜ=zₜ∘\tilde{h}ₜ+(1−zₜ)∘hₜ₋₁, (2)

In the formulation above, σ denotes the element-wise sigmoidal activation function, ⊗ denotes the complex-valued matrix multiplication, modact denotes the activation function corresponding to the modulation gate and ∘ denotes element-wise multiplication. It should be clear that similar symbols used in Equation (1) and Equation (2) denote the same operations. Wₓₘ∈ [symbol] ^{d×2t} and Wₕₘ∈ [symbol] ^{d×2d} are the input-to-hidden and hidden-to-hidden weights, respectively, where i is the complex input dimension and d is the complex hidden size W_{xz}∈ [symbol] ^{d×i} and Wₓₕ-∈ [symbol] ^{d×i} are the input-to-hidden matrices for the update gate and the candidate state respectively. W_{hz}∈ [symbol] ^{d×d}, Wₕₕ-∈ [symbol] ^{d×d} are the hidden-to-hidden matrices for the update gate and the candidate state, respectively. zₜ, mₜ, and h-ₜ are vector notation representations of of the update gate, the modulation gate and the candidate state. For these gates and states, zₜ∈ [symbol] ^{d}, h-ₜ∈ [symbol] ^{d}, and mₜ∈ [symbol] ^{d}. The corresponding biases for these states and gates are represented in vector notation as follows: b_{z}∈ [symbol] ^{d}, bₘ∈ [symbol] ^{d}, bₕ-∈ [symbol] ^{d}. As can be imagined, the subscript of the vector notation of the biases denotes the gate and/or state for which the bias vector applies. hₜ is the vector notation of the hidden state where hₜ∈ [symbol] ^{d} . The modulation gate mₜ tunes the modulus of each complex-valued neuron by either emphasizing it or diminishing it. As it acts only on the modulus, the modulation gate is always positive, and thus requires a non-negative activation function. This activation function may be a sigmoid function, a softplus function (an approximation of the ReLU function), the ReLU function, and the normalized exponential function (i.e. the softmax function).

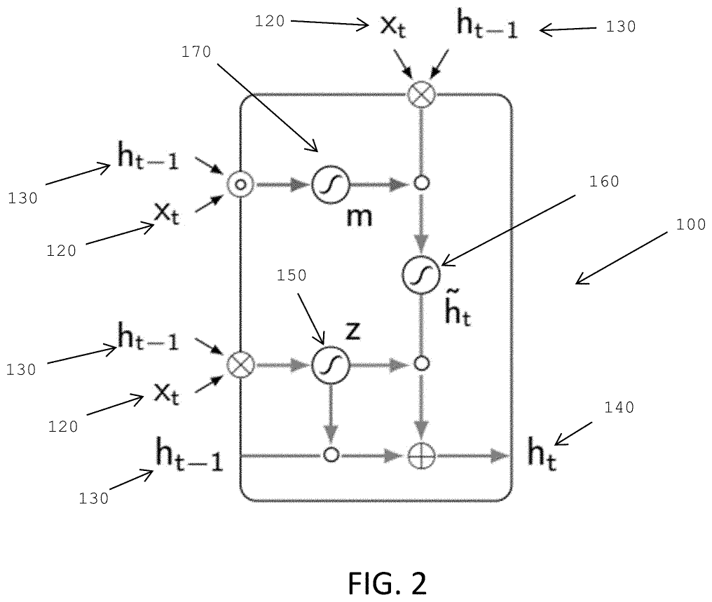

Referring to FIG. 2, a block diagram of the gate mechanism for a CRU is illustrated. As can be seen, the gating mechanism 100 is quite similar to the gating mechanism 10 in FIG. 1. In FIG. 2, the gating mechanism 100 has, as input, an input vector xₜ 120 and an immediately preceding state vector hₜ₋₁ 130 that represents the immediately preceding or immediately previous state of the mechanism 100. The output hₜ 140 is the current state of the gate mechanism and is, from Equation (2), a function of the results of update gate zₜ 150 and of the candidate state \tilde{h}ₜ 160. This candidate state is a result of operations between the two inputs 120, 130 and the result of the modulation gate mₜ 170. The modulation gate results from operations between the two inputs 120, 130. Not shown in the Figure are the weight matrices for each of the gates as well as the bias vectors, with each gate having its own bias vector.

It should be clear that the two gating mechanisms shown in FIGS. 1 and 2 can be implemented as software modules. The update gates, reset gates, and modulation gates can each be implemented as separate and distinct software modules that internally perform the relevant calculations to produce the gate output. As well, the candidate state can also be implemented as a separate module that receives the output of other specific modules as input and internally performs the relevant calculations to output the candidate state. Alternatively, the various gates can be implemented using one or more modules that operate as the relevant activation function for specific gates. Each module that operates as an activation function can then be reused by different gates with the state of each relevant gate being saved for later use. Of course, the activation function module would have, as its input, the input vector, the previous state of the gating mechanism, and whatever weighting matrices and bias vectors need to be applied for that gate.

While the above description of the present invention relates to a software implementation of the gating mechanisms, these gating mechanisms may also be implemented in hardware. Each gating mechanism may be implemented as a self-contained system with the gates being implemented as hardware modules receiving suitable inputs as noted above with their outputs being transmitted/communicated accordingly. Each gating mechanism can thus be an operating hardware neuron in a network. Alternatively, in such a hardware system, each gating mechanism can be, as a self-contained neuron, a combined CPU/storage/RAM system that receives suitable input and operates according to the above equations.

It should be noted that the various embodiments of the present invention may be used for any number of tasks. Experiments have shown that these gating mechanisms are quite suitable for speech and/or audio related tasks. More specifically, the present invention can be used for speech separation tasks where multiple audible sounds in a single sample need to be separated.

The references noted above are as follows:

[1] Martin Arjovsky, Amar Shah, and Yoshua Bengio. Unitary evolution recurrent neural networks. arXiv preprint arXiv:1511.06464, 2015.

[2] Yoshua Bengio, Patrice Simard, and Paolo Frasconi. Learning long-term dependencies with gradient descent is difficult. IEEE transactions on neural networks, 5(2):157-166, 1994.

[3] Kyunghyun Cho, Bart Van Merriënboer, Dzmitry Bandanau, and Yoshua Bengio. On the properties of neural machine translation: Encoder-decoder approaches. arXiv preprint arXiv:1409.1259, 2014.

[4] Ivo Danihelka, Greg Wayne, Benigno Uria, Nal Kalchbrenner, and Alex Graves. Associative long short-term memory. arXiv preprint arXiv:1602.03032, 2016.

[5] N. Q. K. Duong, E. Vincent, and R. Gribonval. Under-determined reverberant audio source separation using a full-rank spatial covariance model. IEEE Transactions on Audio, Speech, and Language Processing, 18(7):1830-1840, Sept 2010.

[6] Ariel Ephrat, Inbar Mosseri, Oran Lang, Tali Dekel, Kevin Wilson, Avinatan Hassidim, William T. Freeman, and Michael Rubinstein. Looking to listen at the cocktail party: A speaker-independent audio-visual model for speech separation. CoRR, abs/1804.03619, 2018.

[7] Cédric Févotte and Jérôme Idier. Algorithms for nonnegative matrix factorization with the beta-divergence. CoRR, abs/1010.1763, 2010.

[8] Cédric Févotte, Nancy Bertin, and Jean-Louis Durrieu. Nonnegative matrix factorization with the itakura-saito divergence: With application to music analysis. Neural Computation, 21(3):793-830, 2009. PMID: 18785855.

[9] Ruohan Gao, Rogério Schmidt Feris, and Kristen Grauman. Learning to separate object sounds by watching unlabeled video. CoRR, abs/1804.01665, 2018.

[10] George M Georgiou and Cris Koutsougeras. Complex domain backpropagation. IEEE transactions on Circuits and systems II: analog and digital signal processing, 39(5):330-334, 1992.

[11] John R. Hershey and Michael Casey. Audio-visual sound separation via hidden markov models. In T. G. Dietterich, S. Becker, and Z. Ghahramani, editors, Advances in Neural Information Processing Systems 14, pages 1173-1180. MIT Press, 2002.

[12] John R. Hershey, Zhuo Chen, Jonathan Le Roux, and Shinji Watanabe. Deep clustering: Discriminative embeddings for segmentation and separation. CoRR, abs/1508.04306, 2015.

[13] Akira Hirose. Complex-valued neural networks: theories and applications, volume 5. World Scientific, 2003.

[14] Sepp Hochreiter. Untersuchungen zu dynamischen neuronalen Netzen. PhD thesis, diploma thesis, institut für informatik, lehrstuhl prof. brauer, technische universität münchen, 1991.

[15] Sepp Hochreiter and Jürgen Schmidhuber. Long short-term memory. Neural computation, 9(8):1735-1780, 1997.

[16] Guoning Hu and DeLiang Wang. Monaural speech segregation based on pitch tracking and amplitude modulation. Trans. Neur. Netw., 15(5):1135-1150, September 2004.

[17] Po-Sen Huang, Kim Minje, Mark Hasegawa-Johnson, and Paris Smaragdis. Deep learning for monaural speech separation. International Conference on Acoustics, Speech, and Signal Processing (ICASSP), 4(12), 2014.

[18] A. Hyvärinen and E. Oja. Independent component analysis: algorithms and applications. Neural Networks, 13(4):411-430, 2000.

[19] Cijo Jose, Moustpaha Cisse, and Francois Fleuret. Kronecker recurrent units. arXiv preprint arXiv:1705.10142, 2017.

[20] Taehwan Kim and Tülay Adah. Approximation by fully complex multilayer perceptrons. Neural computation, 15(7):1641-1666, 2003.

[21] Yuan-Shan Lee, Chien-Yao Wang, Shu-Fan Wang, Jia-Ching Wang, and Chung-Hsien Wu. Fully complex deep neural network for phase-incorporating monaural source separation. In 2017 IEEE International Conference on Acoustics, Speech and Signal Processing, ICASSP 2017, New Orleans, LA, USA, March 5-9, 2017, pages 281-285, 2017.

[22] Antoine Liutkus, Derry Fitzgerald, Zafar Rafii, Bryan Pardo, and Laurent Daudet. Kernel additive models for source separation. IEEE Transactions on Signal Processing, 62(16):4298-4310, Aug. 2014.

[23] Tohru Nitta. Orthogonality of decision boundaries in complex-valued neural networks. Neural Computation, 16(1):73-97, 2004.

[24] David P Reichert and Thomas Serre. Neuronal synchrony in complex-valued deep networks. arXiv preprint arXiv:1312.6115, 2013.

[25] Paris Smaragdis, Bhiksha Raj, and Madhusudana Shashanka. A probabilistic latent variable model for acoustic modeling. In In Workshop on Advances in Models for Acoustic Processing at NIPS, 2006.

[26] Paris Smaragdis, Bhiksha Raj, and Madhusudana Shashanka. Supervised and semi-supervised separation of sounds from single-channel mixtures. In Mike E. Davies, Christopher J. James, Samer A. Abdallah, and Mark D. Plumbley, editors, Independent Component Analysis and Signal Separation, pages 414-421, Berlin, Heidelberg, 2007. Springer Berlin Heidelberg.

[27] Martin Spiertz. Source-filter based clustering for monaural blind source separation. Proc. 12th International Conference on Digital Audio Effects, Italy, 2009, 2009.

[28] Chiheb Trabelsi, Olexa Bilaniuk, Ying Zhang, Dmitriy Serdyuk, Sandeep Subramanian, João Felipe Santos, Soroush Mehri, Negar Rostamzadeh, Yoshua Bengio, and Christopher J Pal. Deep complex networks. arXiv preprint arXiv:1705.09792, 2017.

[29] Tuomas Virtanen. Monaural sound source separation by nonnegative matrix factorization with temporal continuity and sparseness criteria. Trans. Audio, Speech and Lang. Proc., 15(3):1066-1074, March 2007.

[30] Beiming Wang and Mark Plumbley. Investigating single-channel audio source separation methods based on non-negative matrix factorization. ICA Research Network International Work shop, pages 17-20, 09 2006.

[31] DeLiang Wang and Jitong Chen. Supervised speech separation based on deep learning: An overview. CoRR, abs/1708.07524, 2017.

[32] Richard S Zemel, Christopher K I Williams, and Michael C Mozer. Lending direction to neural networks. Neural Networks, 8(4):503-512, 1995.

[33] Michael Zibulevsky and Barak A. Pearlmutter. Blind source separation by sparse decomposition in a signal dictionary. Neural Computation, 13(4):863-882, 2001.

The embodiments of the invention may be executed by a computer processor or similar device programmed in the manner of method steps, or may be executed by an electronic system which is provided with means for executing these steps. Similarly, an electronic memory means such as computer diskettes, CD-ROMs, Random Access Memory (RAM), Read Only Memory (ROM) or similar computer software storage media known in the art, may be programmed to execute such method steps. As well, electronic signals representing these method steps may also be transmitted via a communication network.

Embodiments of the invention may be implemented in any conventional computer programming language. For example, embodiments may be implemented in a procedural programming language (e.g. “C”) or an object-oriented language (e.g. “C++”, “java”, “PHP”, “PYTHON” or “C#”) or in any other suitable programming language (e.g. “Go”, “Dart”, “Ada”, “Bash”, etc.). Alternative embodiments of the invention may be implemented as pre-programmed hardware elements, other related components, or as a combination of hardware and software components.

Embodiments can be implemented as a computer program product for use with a computer system. Such implementations may include a series of computer instructions fixed either on a tangible medium, such as a computer readable medium (e.g., a diskette, CD-ROM, ROM, or fixed disk) or transmittable to a computer system, via a modem or other interface device, such as a communications adapter connected to a network over a medium. The medium may be either a tangible medium (e.g., optical or electrical communications lines) or a medium implemented with wireless techniques (e.g., microwave, infrared or other transmission techniques). The series of computer instructions embodies all or part of the functionality previously described herein. Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies. It is expected that such a computer program product may be distributed as a removable medium with accompanying printed or electronic documentation (e.g., shrink-wrapped software), preloaded with a computer system (e.g., on system ROM or fixed disk), or distributed from a server over a network (e.g., the Internet or World Wide Web). Of course, some embodiments of the invention may be implemented as a combination of both software (e.g., a computer program product) and hardware. Still other embodiments of the invention may be implemented as entirely hardware, or entirely software (e.g., a computer program product).

A person understanding this invention may now conceive of alternative structures and embodiments or variations of the above all of which are intended to fall within the scope of the invention as defined in the claims that follow.

What is claimed is:

1. A method for determining a state of a gating mechanism in a neural network, the method comprising:
a) determining an immediately preceding state vector representing an immediately previous state of said gating mechanism;
b) receiving an input vector;
c) performing an element-wise multiplication between an update gate vector and a candidate state vector;
d) performing an element-wise multiplication between a difference between 1 and said update gate vector and said immediately preceding state vector;
e) adding a result of step c and step d to result in a current state vector representing said state of said gating mechanism;
wherein said update gate vector is based on said input vector, said immediately preceding state vector, an update bias vector, and at least one weight matrix.

2. The method according to claim 1, wherein said method is executed by a software module that forms part of said neural network.

3. The method according to claim 1, further comprising determining a state of a reset gate, said state of said reset gate being based on assessing an element-wise sigmoidal activation function on a sum of three elements, said three elements being:
a complex valued matrix multiplication between said input vector and a first weight matrix;
a complex valued matrix multiplication between said immediately preceding state vector and a second weight matrix; and
a reset bias vector.

4. The method according to claim 1, further comprising determining a state of a modulation gate, said state of said modulation gate being based on assessing an activation function on a sum of three elements, said three elements being:
a multiplication between said input vector and a third weight matrix;
a multiplication between said immediately preceding state vector and a fourth weight matrix; and
a modulation bias vector.

5. The method according to claim 4, wherein said activation function is one of:
a sigmoid function;
a softplus function; and
a normalized exponential function.

6. A system for determining a current state of a gating mechanism in a neural network, the system comprising:
a candidate module for determining a candidate state for said gating mechanism based on:
an input vector,
an immediately preceding state vector representing an immediately previous state of said gating mechanism,
at least one candidate weight matrix, and
a candidate bias vector;
an update gate module for determining an update gate vector based on:
said input vector;
said immediately preceding state vector;
an update bias vector; and
at least one update weight matrix;
wherein
a result of said candidate module and a result of said update gate module are multiplied in an element-wise manner to result in a first intermediate product;
a result of said update gate module and said immediately preceding state vector are multiplied in an element-wise manner to result in a second intermediate product;
a sum of said first intermediate product and said second intermediate product results in said current state of said gating mechanism.

7. The system according to claim 6, further comprising a reset gate module for determining a reset gate vector, said reset gate vector being based on assessing a sigmoidal activation function on:
said input vector;
said immediately preceding state vector;
a reset bias vector; and
at least one reset weight matrix;
and wherein said candidate state is further based on said reset gate vector.

8. The system according to claim 6, further comprising a modulation gate module for determining a modulation gate vector, said modulation gate vector being based on assessing an activation function on:
said input vector;
said immediately preceding state vector;
a modulation bias vector; and
at least one modulation weight matrix;
and wherein said candidate state is further based on said modulation gate vector.

9. The system according to claim 8, wherein said activation function is one of:
a sigmoid function;
a softplus function; and
a normalized exponential function.
